(19) United States
(12) Patent Application Publication
(10) Pub. No.: US 2011/0228486 A1
(43) Pub. Date: Sep. 22, 2011

(54) Power supply with low touch-temperature surface

(75) Inventor: Thomas W. Lanni, Laguna Niguel, CA (US)

(73) Assignee: COMARCO WIRELESS TECHNOLOGIES, INC., Lake Forest, CA (US)

(21) Appl. No.: 12/661,431

(22) Filed: Mar. 17, 2010

(51) Int. Cl. H05K 7/20; H05K 7/02

(52) U.S. Cl. 361/722; 361/807

(57) ABSTRACT

A power supply provides a low touch-temperature surface by utilizing a plurality of spaced apart pegs which extend from a surface of a case away from heat generating components enclosed within the case. The top and side surfaces of the pegs and the surface of the case not occupied by the pegs are entirely directly exposed to ambient air. The tops of the pegs provide a touch surface having a temperature which is cooler than that at the base of the pegs. The pegs are preferably arranged to minimize heat transfer between adjacent pegs.

### FIELD OF THE INVENTION

The present invention relates to power supplies, also known as power adapters and power converters. In particular, the invention concerns a power supply which utilizes a case with a low touch-temperature surface.

### BACKGROUND OF THE INVENTION

Referring to FIG. 1, there is shown in block diagram form a conventional power supply used to provide DC power to portable electronic devices, such as notebook computers, cellular telephones, PDAs, MP3 players and the like. The power supply 2 is capable of receiving an input voltage from a DC power source, such as an automobile or airplane power port, as well as from an AC power source, such as a household wall outlet. Conversion circuitry 4 converts the input voltage to a DC output voltage which may be provided to an electronic device, such as a notebook PC. The DC voltage provided to the electronic device may be fixed in the case, for example, that the power supply 2 is dedicated for use with one model of notebook PC. Alternatively, a signal 6 may be used to program the conversion circuitry 4 to provide a particular voltage selectable from a range of output voltages. In this way, the power supply may be used with a variety of electronic devices having differing input voltage requirements. Conversion circuitry and various connector adapters, cables and switches used to program the conversion circuitry are disclosed in U.S. Pat. No. 7,450,390, the disclosure of which is incorporated herein by reference; particular reference is made to FIGS. 7A-7C; 24-40; and 51 of U.S. Pat. No. 7,450,390.

The conversion circuitry is typically housed in a case which surrounds a printed circuit board(s). Components (e.g., transformers, transistors, resistors, capacitors, etc.) making up the conversion circuitry are fixed to the circuit board(s) and are interconnected by wiring traces on or within the circuit board. For ease of portability and user convenience, it is desirable to provide a power supply which is physically small in thickness, as well as in length and width. However, since the conversion circuitry components generate heat in operation, a problem is encountered with small dimensioned power supplies in that their surface temperature may reach undesirable levels. This in turn causes risk of injury to the power supply user.

Efforts to lower the surface temperature of power supplies have included use of louvers and openings in the case to provide air gaps to promote air circulation (see, e.g., U.S. Pat. No. 7,450,390). While configurations of this type lower the surface temperature of the case, they require use of a precisely fitted layer(s) to resist entry of liquids into the case. In addition, the presence of openings or air gaps weaken the structural integrity of the case. It would be beneficial for a power supply to have a low touch-temperature, with good structural integrity and low risk of liquid penetration.

### SUMMARY OF THE INVENTION

The present invention is a power supply having a low touch-temperature surface. The power supply includes conversion circuitry to convert an input voltage to an output voltage. The conversion circuitry is housed in a case having a surface and a plurality of spaced apart pegs which extend from the surface away from the conversion circuitry. At their tops, the pegs provide a touch surface having a temperature cooler than that at the base of the pegs.

The pegs have a unitary construction with the case surface such that there is no joint between the case surface and a peg in the location where the case surface transitions into a peg. The case surface and the top and side surfaces of the pegs are preferably entirely directly exposed to ambient air. In an embodiment, the case is assembled from top and bottom plastic housings which matingly engage to enclose a circuit board on which conversion circuitry components are disposed. Injection molding is the preferred method for forming the housings. The pegs may be arranged in a particular row and column configuration to minimize heat transfer between adjacent pegs.

### BRIEF DESCRIPTION OF THE DRAWINGS

FIG. 1 is a block diagram of a conventional power supply;

FIG. 2 is a perspective view of a power supply according to an embodiment of the invention;

FIG. 3 is an expanded perspective view of the power supply;

FIG. 4 is an perspective view of a case of the power supply;

FIG. 5 is a cross sectional perspective view of the case taken along the line V-V of FIG. 4;

FIG. 6 is a top view of the case of the power supply;

FIG. 7 is a cross sectional view of the case taken along the line VII-VII of FIG. 6;

FIG. 8 is an enlarged cross-sectional view of a cross section of the case taken within the circular line VIII-VIII of FIG. 7; and

FIG. 9 is an enlarged view of the top of the case taken within the circular line IX-IX of FIG. 6.

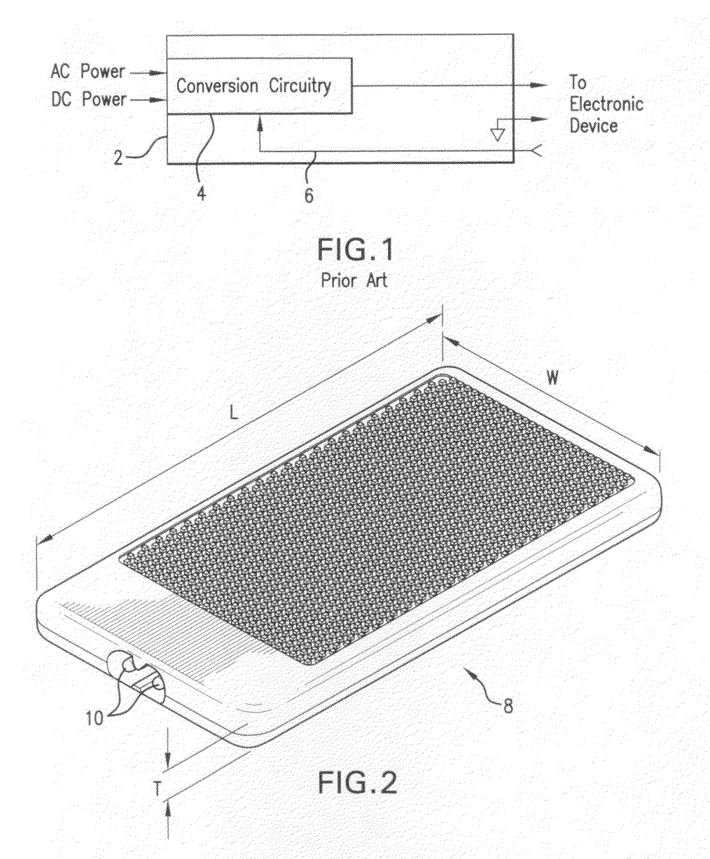

### DETAILED DESCRIPTION OF THE PREFERRED EMBODIMENT

FIG. 2 is a perspective view of a power supply according to an embodiment of the invention. The power supply 8 has, in the illustrated embodiment, the shape of a right parallelepiped with rounded edges and corners. The unit has a length L, a width W and a thickness T. The dimensions may vary as a function of factors, such as the power output capacity of the power supply. In general, the area of the top and bottom surface areas, defined by “L” and “W”, should be much greater than the thickness “T”. In a preferred embodiment, the length L is about 119.14 mm, the width W is about 64.58 mm and the thickness T is about 11.00 mm. A pair of input terminals 10 are disposed along one width of the power supply to receive, via a cable, AC or DC input power.

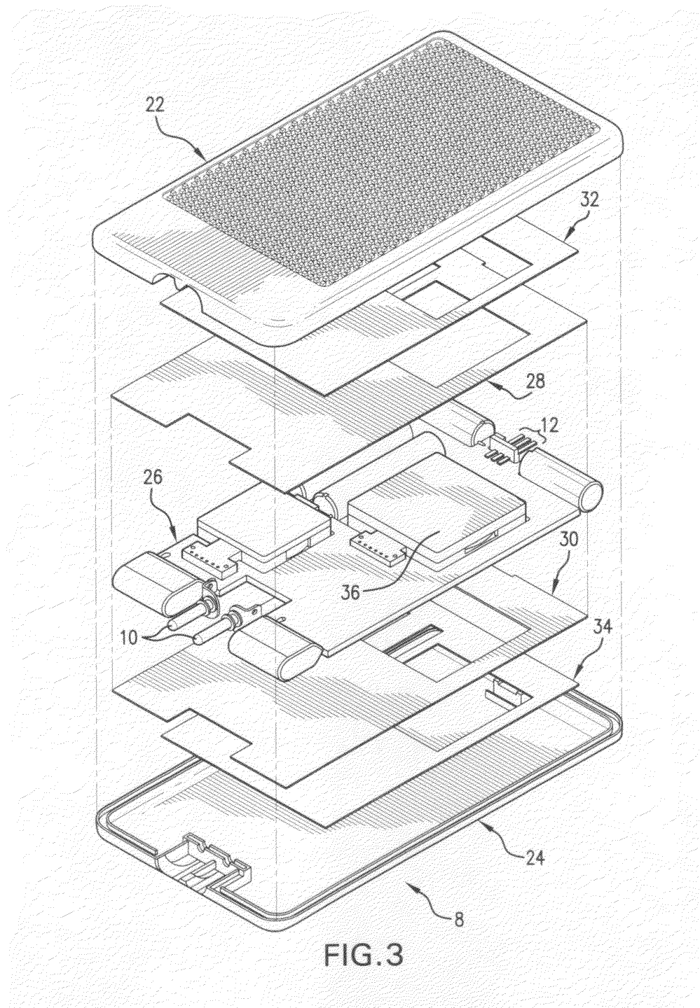

FIG. 3 is an expanded perspective view of the power supply 8. A top housing 22 matingly engages with a bottom housing 24 to enclose a circuit board 26. The circuit board has affixed to it electrical components, such as transformers, transistors, resistors, capacitors, etc. (only some of which are shown in FIG. 3) constituting conversion circuitry for converting the AC or DC voltage applied to input terminals 10 to a regulated DC output voltage. The DC output voltage is provided at a pair of the terminals 12. The third terminal of terminals 12 may be used for receiving a signal which programs the conversion circuitry to provide a particular voltage selectable from a range of output voltages.

To ensure electrical isolation, the circuit board and components are preferably sandwiched between a pair of insulator layers 28, 30. In a preferred embodiment, the insulator layers are each made of double-layer polyethylene naphthalate (PEN). Between the insulator layer 28 and the top housing 22, there is disposed a heat spreading layer 32. Likewise, between the insulator layer 30 and the bottom housing 24, there is disposed a heat spreading layer 34. The heat spreading layers 32, 34 are preferably made of aluminum, but other suitable heat conducting materials may be used. To further enhance heat distribution within the power supply, thermally conductive potting material, such as silicone or epoxy, may be pumped into the unit to fill air spaces therein with the thermally conductive potting. Preferably, the layers 32, 34 are made of a material which shields electromagnetic radiation generated by the power supply. Each of the layers 28, 30, 32, 34 may include cut-outs in selected regions to provide more clearance room between the top and bottom housing 22, 24 for some of the conversion circuitry components, such as a transformer 36.

The top and bottom housings are made from high impact plastic, such as acrylonitrile butadiene styrene (ABS), polyphenylene oxide (PPO), thermoplastic polycarbonate resin or nylon. Injection molding is the preferred method for forming the housings. The top and bottom housings may matingly engage by a snap lock or force fit or an ultrasonic weld.

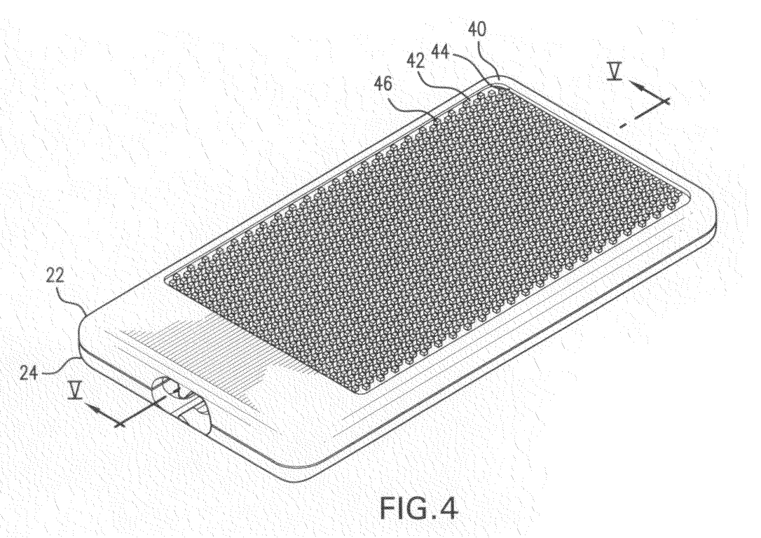

FIG. 4 is a perspective view of the top housing 22 and bottom housing 24 fitted together to form the case without the circuit board disposed therein. The top housing 22 has an upper surface 40 around the periphery of the housing. The surface 40 may have a smooth texture. Inset from the periphery of the top housing is a generally rectangular region which defines a floor 42. The floor is preferably disposed above the heat generating components of an assembled power supply. The floor 42 may be defined by the area above the perimeter of the heat spreading layer 32.

Although not necessary, in the illustrated embodiment, the floor 42 is at a level which is lower than, i.e., below, the upper surface 40. In such an embodiment, a wall 44 extends from the floor 42 to the upper surface 40 of the top housing 22. The wall 44 is disposed around the perimeter of the floor 42. Rising from the floor are a plurality of pegs 46. The pegs are spaced apart from one another and may be arranged in offset rows and columns. The pegs may have a cylindrical form, but other geometric shapes may be utilized. In the illustrated embodiment, the pegs are shaped as square posts. Preferably, the pegs have a unitary construction with the floor. That is, there is no joint between the floor and a peg in the location where the floor transitions into the peg. It is also preferable that nothing overlies the floor or the pegs so that the top surfaces of the floor and the pegs and the side surfaces of the pegs are entirely directly exposed to the ambient air. This lessens the opportunity for moisture or debris being retained on the case and enhances the cooling effect of the pegs.

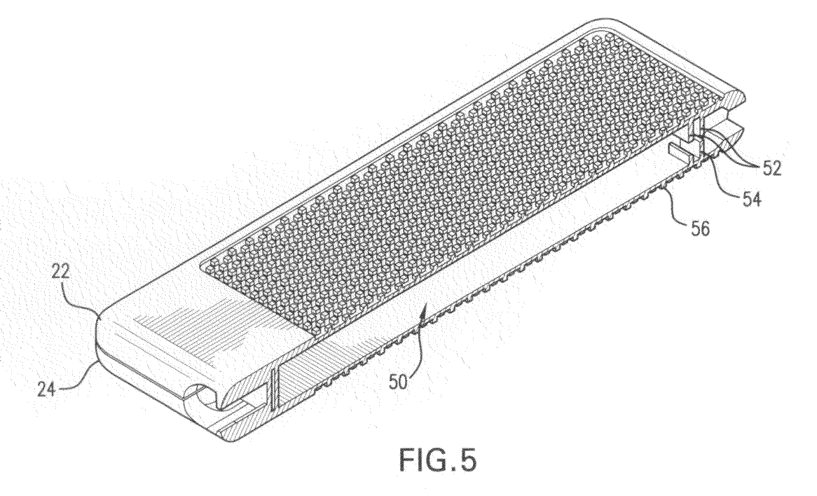

FIG. 5 is a cross sectional perspective view of the case taken along the line V-V of FIG. 4. The figure illustrates a chamber 50 in which the circuit board and components are disposed in an assembled power supply. A pair of spaced apart downwardly extending upper legs 52 may be used to engage an upwardly extending lower leg 54 to assist in aligning the top housing 22 with the bottom housing 24. In the preferred embodiment, the bottom housing 24 includes an upper surface, a floor, a wall and pegs corresponding to those illustrated in FIG. 4. The pegs 56 of the bottom housing extend downwardly from the floor when the power supply is “upright.” Owing to its construction, the power supply is operable whether it is “right side up” or “upside down.” While the following description primarily concerns the top housing 22, it is likewise applicable to the bottom housing 24.

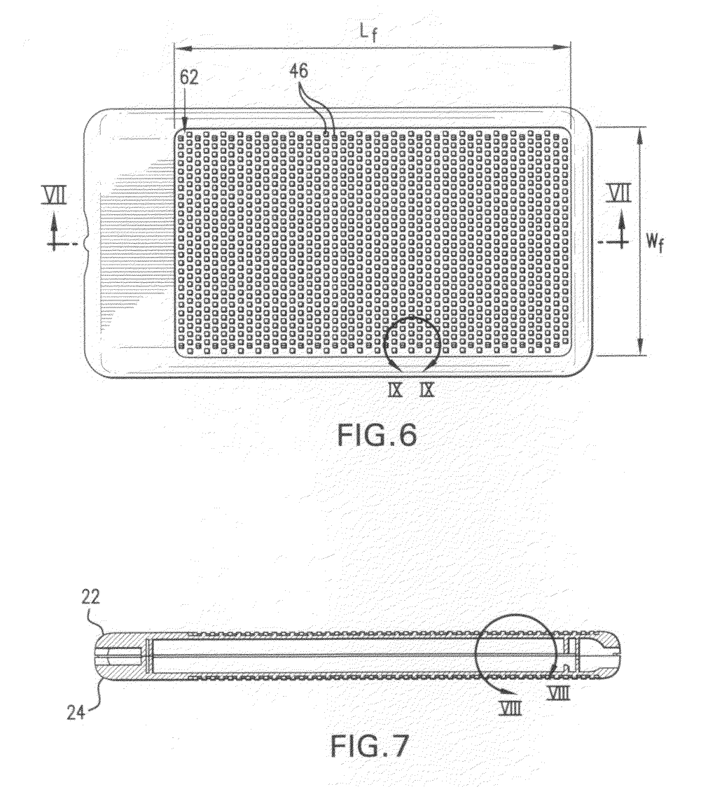

FIG. 6 is a top view of the case of the power supply. The pegs 46 are preferably arranged in rows and columns with an aisle 62 between the pegs in a first column and the pegs of an adjacent column. The rows and columns are arranged such that a peg in an odd-numbered column is spaced apart from the peg in the same row of the next odd-numbered column by unoccupied floor extending a distance equal to the length of a peg plus the width of two aisles 62. The same is true for a peg in an even-numbered column relative to a peg of the same row in the next even-numbered column. The pegs in adjacent rows of the same column are separated by unoccupied floor extending a distance equal to the width of a peg, but there is not an aisle, as there is for the columns. In the illustrated embodiment, all of the aisles 62 have substantially the same width.

It is preferable that the floor area occupied by the pegs be equal to or less than one fourth of the total floor area. Stated another way, the floor area not occupied by the pegs should be at least three times the floor area which is occupied by the pegs. Such an arrangement is beneficial in ensuring that each peg is sufficiently isolated from neighboring pegs so as not to transfer heat therebetween. The overall effect of the pegs is to significantly lower the touch-temperature of the case of an operating power supply. That is, the temperature at the top of the pegs is significantly lower than the temperature at the top surface of the floor, which would be the touch-temperature of a case without pegs.

Referring to FIG. 9, which is an enlarged view of the top of the case taken within the circular line IX-IX of FIG. 6, a peg 46 has a length Lₚ and a width Wₚ. The aisles 62 have a width Wₐ. In the illustrated embodiment, each of Lₚ, Wₚ and Wₐ is 1.00 mm. Thus, one peg occupies one square millimeter of floor area.

The 1.0 mm dimensions for Lₚ, Wₚ and Wₐ are illustrative. It is not necessary for Lₚ, Wₚ and Wₐ to be equal. Some types of pegs are better described by dimensions other than length and width, such as a radius for a cylindrical peg. In general, the peg size and spacing should be such that heat transfer between the pegs is minimal, the pegs are not easily broken off from the floor and user fingertips are prevented from touching the top surface of the floor by the pegs. Pegs having a length and a width and a spacing in the range of about 0.5 mm-5.0 mm are preferable.

Referring again to the illustrated embodiment of FIG. 6, there are 51 rows of pegs with 23 pegs in each row and two (outer) rows of pegs with 22 pegs in each row for a total of 1,217 pegs. In this embodiment, the length L_{f} of the floor is about 93 mm and the width W_{f} of the floor is about 55 mm. Thus, the total area of the floor is approximately 5,115 mm². Since each of the 1,217 pegs occupies 1 mm², the total floor area occupied by the pegs is 1,217 mm². This leaves 3,898 mm² of floor area not occupied by the pegs, which is more than three times the amount of the floor area which is occupied by the pegs.

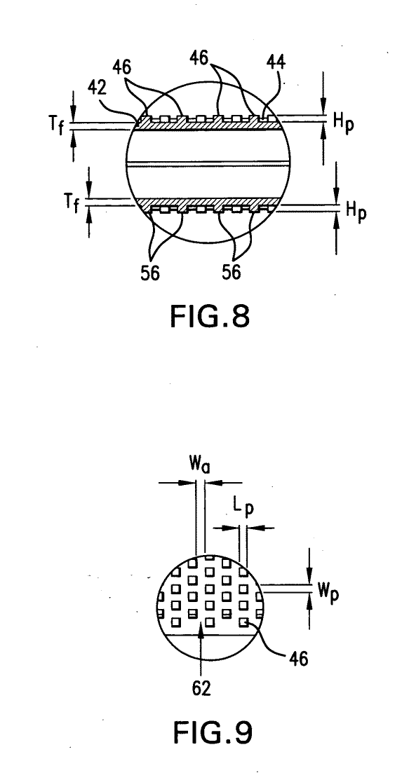

FIG. 7 is a cross-sectional view of the case taken along the line VII-VII of FIG. 6. The figure illustrates the top housing 22 and the bottom housing 24 fitted together to form the case. FIG. 8 is an enlarged cross-sectional view of the case taken within the circular line VIII-VIII of FIG. 7. FIG. 8 illustrates that the floor 42 has a thickness T_{f} in regions of the floor on which the pegs are not disposed. Such regions include an aisle 62 and the area between adjacent pegs of the same column. A peg has a height Hₚ relative to the top surface of the floor 42. The height of the pegs may range from about 0.5 mm to about 2.0 mm. In the preferred embodiment, the height of the pegs is about 0.75 mm. It is desirable that the floor thickness T_{f} be at least equal to the peg height Hₚ, and preferably slightly (e.g., about 1.25 to 1.5 times) greater.

From the pegs labeled by reference numeral 46 in FIG. 8, it can be seen that the pegs have a unitary construction with the floor such that there is no joint between the floor and a peg in the location where the floor transitions into the peg. The pegs adjacent to those labeled 46 in FIG. 8 have the same construction. However, since they are located “behind” the cross-section line VII-VII of FIG. 6, such pegs are not shown in cross-section and a line representing the top surface of the floor 42 is shown under those pegs. In the cross sectional view of FIG. 8, the wall 44 can be seen at the end of an aisle 62. The height of the pegs on the interior of the floor is preferably somewhat (about 25-50%) higher than the top surface of the wall 44. The pegs in the rows and columns near the wall may be contoured so as to be substantially flush with the top of the wall 44, i.e., the upper surface 40.

While the description above refers to particular embodiments of the present invention, it will be understood that modification may be made without departing from the spirit thereof. For example, a case having pegs as described above may be utilized to enclose heat generating components which function to perform work other than power conversion. The following claims are intended to cover all modifications which fall within the scope and spirit of the present invention. The presently disclosed embodiments are therefore to be considered in all respects as illustrative and not restrictive, the scope of the invention being indicated by the claims, rather than the foregoing description, and all changes which come within the meaning and range of equivalence of the claims are therefore intended to be embraced therein.

What is claimed is:

1. A power supply comprising:
conversion circuitry to convert an input voltage to an output voltage; and
a case enclosing the conversion circuitry, the case having a surface and a plurality of spaced apart pegs which extend from the surface away from the conversion circuitry, the pegs having a unitary construction with the surface, wherein the surface not occupied the pegs and top and side surfaces of the pegs are entirely directly exposed to ambient air.

2. The power supply according to claim 1, wherein the case is made of plastic.

3. The power supply according to claim 1, wherein the pegs are shaped as posts having four sides.

4. The power supply according to claim 3, wherein the sides of the pegs have length and width dimensions in a range of about 0.5 mm-5.0 mm.

5. The power supply according to claim 4, wherein the pegs have a height in a range of about 0.5 mm-2.0 mm.

6. The power supply according to claim 1, wherein the pegs are arranged in rows and columns.

7. The power supply according to claim 6, wherein an aisle is disposed between each pair of adjacent columns.

8. A power supply comprising:
conversion circuitry to convert an input voltage to an output voltage; and
a case enclosing the conversion circuitry, the case having a top, a portion of the top disposed above heating generating components of the conversion circuitry defining a floor, a plurality of spaced apart pegs extending from the floor away from the conversion circuitry, wherein an area of the floor not occupied by the pegs is at least three times greater than an area of the floor which is occupied by the pegs.

9. The power supply according to claim 8 further including a heat spreading layer disposed between the heat generating components and the top of the case, the heat spreading layer having a perimeter which is generally coextensive with the floor.

10. The power supply according to claim 8, wherein the top has an upper surface and the floor is disposed at a height lower than the upper surface.

11. The power supply according to claim 10, wherein a majority of the pegs have a height which is greater than a distance separating the upper surface and the floor.

12. The power supply according to claim 11, wherein pegs disposed near a perimeter of the floor have a height substantially equal to the distance separating the upper surface and the floor.

13. The power supply according to claim 8, wherein the floor in an area not occupied by the pegs has a thickness which is equal to or greater than a height of the pegs.

14. The power supply according to claim 13, wherein the floor in an area not occupied by the pegs has a thickness which is 1.25 to 1.5 times the height of the pegs.

15. A power supply comprising:
conversion circuitry to convert an input voltage to an output voltage; and
a case enclosing the conversion circuitry, the case having a surface and a plurality of spaced apart pegs which extend from the surface away from the conversion circuitry, the pegs having a length and a width and being arranged in rows and columns such that there is an aisle, having a width, between each pair of adjacent columns of pegs, wherein
a peg in an odd-numbered column is spaced apart from the peg in the same row of the next odd-numbered column by unoccupied floor extending a distance equal to the length of a peg plus the width of two aisles,
a peg in an even-numbered column is spaced apart from the peg in the same row of the next even-numbered column by unoccupied floor extending a distance equal to the length of a peg plus the width of two aisles, and
the pegs in adjacent rows of the same column are spaced apart by unoccupied floor extending a distance equal to the width of a peg.

16. The power supply according to claim 15, wherein the length of the pegs is in a range of about 0.5 mm-5.0 mm and the width of the pegs is in a range of about 0.5 mm-5.0 mm.

17. The power supply according to claim 16, wherein the length and the width of the pegs are equal.

18. The power supply according to claim 17, wherein the length and the width of the pegs are about 1.0 mm.

19. The power supply according to claim 16, wherein the pegs have a height in a range of about 0.5 mm to 2.0 mm.

20. The power supply according to claim 19, wherein the pegs have a height of about 0.75 mm.
